(19) United States
(12) Patent Application Publication
(10) Pub. No.: US 2020/0373464 A1
(43) Pub. Date: Nov. 26, 2020

(54) GRAPHENE BASED CONTACT LAYERS FOR ELECTRONIC DEVICES

(71) Applicant: Paragraf Limited, Somersham (DE)

(72) Inventors: Simon Thomas, Somersham (GB); Ivor Guiney, Somersham (GB)

(73) Assignee: Paragraf Limited, Somersham (GB)

(21) Appl. No.: 16/961,059

(22) PCT Filed: Jan. 10, 2019
(86) PCT No.: PCT/GB2019/050060

§ 371 Date: Jul. 9, 2020

(30) Foreign Application Priority Data
Jan. 11, 2018 (GB) 1800449.9

(51) Int. Cl. H01L 33/42; C01B 32/186; C23C 16/26; C30B 25/02; C30B 29/02; C23C 16/30; H01L 31/0224; H01L 31/18

(52) U.S. Cl. CPC H01L 33/42; C01B 32/186; C23C 16/26; C30B 25/02; C30B 29/02; H01L 2933/0016; H01L 31/022466; H01L 31/1884; C01B 2204/22; C01B 2204/04; C23C 16/303

(57) ABSTRACT

A method for the production of a light-sensitive or light-emitting electronic device, the method comprising forming a light-sensitive or light-emitting device by MOCVD in an MOCVD reaction chamber; and forming a graphene layer structure on the light-sensitive or light-emitting device in the MOCVD reaction chamber; wherein the graphene layer structure comprises from 2 to 10 layers of graphene and wherein the graphene layer structure provides an electrical contact for the device.

### REFERENCE TO RELATED APPLICATIONS

This application is a U.S. national stage application based on PCT/GB2019/050060, filed Jan. 10, 2019, claiming priority to Great Britain application no. 1800449.9, filed Jan. 11, 2018, the entire disclosures of which are incorporated herein by reference.

### FIELD OF THE INVENTION

The present invention relates to a method for the production of a light-sensitive or light-emitting electronic device. In particular, the method of the invention provides an improved approach to making contacts on a device where the contacts need to be electrically conductive, but also transparent to light, and the invention relies upon graphene to achieve this.

### BACKGROUND

Graphene is a well-known material with a plethora of proposed applications driven by the material's theoretical extraordinary properties. Good examples of such properties and applications are detailed in ‘The Rise of Graphene’ by A. K. Geim and K. S. Novoselev, Nature Materials, vol. 6, March 2007, 183-191.

WO 2017/029470, the content of which is incorporated herein by reference, discloses methods for producing two-dimensional materials. Specifically, WO 2017/029470 discloses a method of producing two-dimensional materials such as graphene, comprising heating a substrate held within a reaction chamber to a temperature that is within a decomposition range of a precursor, and that allows graphene formation from a species released from the decomposed precursor; establishing a steep temperature gradient (preferably>1000° C. per meter) that extends away from the substrate surface towards an inlet for the precursor; and introducing precursor through the relatively cool inlet and across the temperature gradient towards the substrate surface. The method of WO 2017/029470 may be performed using vapour phase epitaxy (VPE) systems and metal-organic chemical vapour deposition (MOCVD) reactors.

The method of WO 2017/029470 provides two-dimensional materials with a number of advantageous characteristics including: very good crystal quality; large material grain size; minimal material defects; large sheet size; and are self-supporting. However, there remains a need for fast and low-cost processing methods for fabricating devices from the two-dimensional materials.

US 2015/0044367 discloses a method for forming monolayer graphene-boron nitride heterostructures. Specifically, this document teaches the formation of graphene on a metallic surface, utilizing the catalytic interaction to breakdown a carbon containing precursor. Additionally, this process appears to require ultra-low vacuum (1×10-8 Torr).

US 2016/0240719 relates to semiconductor devices comprising 2D-materials and methods of manufacture thereof. This document relates to CVD methods.

In Chinese Physics B, vol. 23, No. 9, 2014 Zhao et al. relates to the growth of graphene on gallium nitride using chemical vapour deposition. Specifically, this paper uses MOCVD to grow GaN then transfers the wafer from the MOCVD reactor to a CVD reactor in order to attempt to grow graphene.

Neither US 2016/0240719 nor Chinese Physics B, vol. 23, No. 9, 2014 provide results showing the production of graphene. Instead it is likely that amorphous carbon is being produced. It is known in the art that in order to produce graphene by CVD a metal catalyst is needed.

### BRIEF DESCRIPTION OF THE FIGURES

FIG. 1 shows a schematic cross-section of a graphene-layer growth chamber for use in the method described herein.

FIG. 2 shows an example of an LED structure made according to the present disclosure.

### SUMMARY OF THE INVENTION

It is an object of the present invention to provide an improved method for the production of a light-sensitive or light-emitting electronic device which overcomes, or substantially reduce, problems associated with the prior art or at least provide a commercially useful alternative thereto.

Accordingly, the present invention provides a method for the production of a light-sensitive or light-emitting electronic device, the method comprising:

forming a light-sensitive or light-emitting device by MOCVD in an MOCVD reaction chamber;

forming a graphene layer structure on the light-sensitive or light-emitting device by MOCVD in the MOCVD reaction chamber;

wherein the graphene layer structure comprises from 2 to 10 layers, preferably 2 to 6 layers, of graphene and wherein the graphene layer structure is for providing an electrical contact for the device.

### DETAILED DESCRIPTION OF PREFERRED EMBODIMENTS

The present disclosure will now be described further. In the following passages different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The inventors have found that by growing thin layers of graphene on a light-sensitive or light-emitting electronic device, they can achieve an optically transparent layer with optimal electrical properties, while at the same time producing cost-effective electrical contacts from a readily available element. That is, thin layers of graphene are sufficiently optically transparent. Moreover, the use of MOCVD to grow the graphene gives high quality contacts. Finally, as a complete process involving the manufacture of the device and contacts in a single chamber, the efficiency and speed of the process is unprecedented.

MOCVD is a term used to describe a system used for a particular method for the deposition of layers on a substrate. While the acronym stands for metal-organic chemical vapour deposition, MOCVD is a term in the art and would be understood to relate to the general process and the apparatus used therefor and would not necessarily be considered to be restricted to the use of metal-organic reactants or to the production of metal-organic materials. Instead, the use of this term indicates to the person skilled in the art a general set of process and apparatus features. MOCVD is further distinct from CVD techniques by virtue of the system complexity and accuracy. While CVD techniques allow reactions to be performed with straight-forward stoichiometry and structures, MOCVD allows the production of difficult stoichiometries and structures. An MOCVD system is distinct from a CVD system by virtue of at least the gas distribution systems, heating and temperature control systems and chemical control systems. An MOCVD system typically costs at least 10 times as much as a typical CVD system. CVD techniques cannot be used to achieve high quality graphene layer structures.

MOCVD can also be readily distinguished from atomic layer deposition (ALD) techniques. ALD relies on step-wise reactions of reagents with intervening flushing steps used to remove undesirable by products and/or excess reagents. It does not rely on decomposition or dissociation of the reagent in the gaseous phase. It is particularly unsuitable for the use of reagents with low vapour pressures such as silanes, which would take undue time to remove from the reaction chamber.

The present invention relates to a method for the production of a light-sensitive or light-emitting electronic device. Such devices are well known in the art and include devices such as LEDs and OLEDs on the one hand, and solar panels and light sensors on the other. These are the most preferred embodiments. The manufacture of such devices are well known and disparate, but they all have a surface from which light is emitted or received and they all have a need for electrical contacts. Therefore the invention has broad application.

The optical transparency can be ascertained with a simple transparency meter. Alternatively, the absorption coefficient can be calculated and transparency becomes 1-(pi*alpha). By way of example, a monolayer of graphene is approximately 97.7% transparent, which compares well with ITO (main competitor material) in the visible region of the spectrum (˜91%) and in the deep UV region of the spectrum (˜82%). The inventors have also found that when you compare a monolayer of undoped graphene to a doped monolayer doped with, for example, bromine, the sheet resistance of the doped layer would be better than that of the undoped layer, while still achieving the same optical transparency.

The light-sensitive or light-emitting electronic device will generally be formed on a substrate. For clarity, in the passages which follow, this substrate which forms part of the device itself will be referred to as the primary substrate. As will be appreciated, the device forms the substrate on which the graphene layer is formed. Therefore the device on which the graphene is formed will be referred to as the secondary substrate hereafter.

The method involves a first step of forming a light-sensitive or light-emitting device by MOCVD in an MOCVD reaction chamber. Techniques for the manufacture of such devices are well known in the art. By way of example, a GaN LED may be grown by MOCVD and would provide an optionally doped GaN uppermost layer for the emission of light. This uppermost layer would then provide the support for the growth of graphene as discussed herein. Although the term device is used, it should be appreciated that at this stage the device is incomplete since it will be missing its final electrode. Nonetheless, it will have the necessary layers suitable for emitting or capturing light if it were to be connectable to a circuit.

Generally it is preferred to have a light-sensitive or light-emitting device that is as thin as possible to ensure thermal uniformity across the secondary substrate during graphene production. Suitable thicknesses are 100 to 500 microns, preferably 200 to 400 microns and more preferably about 300 microns. The minimum thickness of the device is however determined in part by the device's mechanical properties and the maximum temperature at which the device is to be heated. The maximum area of the device is dictated by the size of the close coupled reaction chamber. Preferably the substrate has a diameter of at least 2 inches, preferably 2 to 24 inches and more preferably 6 to 12 inches. This substrate can be cut after growth to form individual devices using any known method. This device can be cut after growth to form individual devices using any known method.

According to the second step, a graphene layer structure is formed on the light-sensitive or light-emitting device (secondary substrate) by MOCVD in the MOCVD reaction chamber. Graphene is a well-known term in the art and refers to an allotrope of carbon comprising a single layer of carbon atoms in a hexagonal lattice. The term graphene used herein encompasses structures comprising multiple graphene layers stacked on top of each other. The term graphene layer is used herein to refer to a graphene monolayer. Said graphene monolayers may be doped or undoped. The graphene layer structures disclosed herein are distinct from graphite since the layer structures retain graphene-like properties. MOCVD growth of graphene is discussed in WO 2017/029470.

The graphene layer structure has from 2 to 10 layers of graphene, preferably 2 to 6 layers. This number of layers is a balance between the optical transparency required and the electrical properties achieved. The thicker the layer the worse the transparency but the better the conduction. A more preferred number of layers is 3 to 4. For certain applications, UV or IR for example, transparency at a thickness of from 6 to 10 layers will be sufficient and the conduction will be improved. The graphene layer structure preferably extends across an entirety of the light-emitting or light-receiving surface of the device.

The graphene layer structure is for providing an electrical contact for the device. That is, the graphene layer structure acts as an electrical contact in the device. In other words, for the light-sensitive or light-emitting device to function as intended, it is to be connected to a circuit at least via the graphene layer, relying on the graphene layer's electrical conductivity properties. The graphene layer can, therefore, be formed in a number of ways. It can be formed across the entire surface and then, if necessary, selectively etched or laser ablated away. Alternatively it can be formed through a mask to provide portions without the contact thereon.

Preferably the method further comprises connecting the graphene-layer-structure-coated light-sensitive or light-emitting device into a circuit. The circuit will connect to the device via electrical communication through the graphene layer and at least one other location. For example, on an LED, one connection will be through an electrically conductive portion of the LED substrate and the other through the graphene layer, whereby an electrical potential applied to the substrate and the graphene will cause light to be emitted by the intervening structure.

Preferably the step of forming a graphene layer structure on the light-sensitive or light-emitting device by MOCVD in the MOCVD reaction chamber comprises:

providing the light-sensitive or light-emitting device as a substrate on a heated susceptor in a reaction chamber, the chamber having a plurality of cooled inlets arranged so that, in use, the inlets are distributed across the substrate and have a constant separation from the substrate,

supplying a flow comprising a precursor compound through the inlets and into the reaction chamber to thereby decompose the precursor compound and form graphene on the substrate,

wherein the inlets are cooled to less than 100° C., preferably 50 to 60° C., and the susceptor is heated to a temperature of at least 50° C. in excess of a decomposition temperature of the precursor.

The device on which the graphene is based may be any suitable device capable of being formed by MOCVD. The device may be formed by deposition on a primary substrate. Preferably the primary substrate comprises sapphire or silicon carbide, preferably sapphire. Other suitable primary substrates include silicon, nitride semiconductor materials (AlN, AlGaN, GaN, InGaN and complexes of), arsenide/phosphide semiconductors (GaAs, InP, AllnP and complexes of), and diamond. Most preferred substrates are electrically conductive substrates since this can then be used to form another electrical contact in the device. The methods of device growth are well known, so the following discussion will focus on the second step of graphene growth on the secondary substrate.

The secondary substrate is provided on a heated susceptor in a reaction chamber as described herein. Reactors suitable for use in the present method are well known and include heated susceptor capable of heating the secondary substrate to the necessary temperatures. The susceptor may comprise a resistive heating element or other means for heating the secondary substrate.

The chamber has a plurality of cooled inlets arranged so that, in use, the inlets are distributed across the secondary substrate and have a constant separation from the secondary substrate. The flow comprising a precursor compound may be provided as a horizontal laminar flow or may be provided substantially vertically. Inlets suitable for such reactors are well known and include Planetary and Showerhead reactors available from Aixtron.

The spacing between the secondary substrate surface upon which the graphene is formed and the wall of the reactor directly above the substrate surface has a significant effect on the reactor thermal gradient. It is preferred that the thermal gradient is as steep as possible which correlates to a preferred spacing that is as small as possible. A smaller spacing changes the boundary layer conditions at the secondary substrate surface that in turn promotes uniformity of graphene layer formation. A smaller spacing is also highly preferred as it allows refined levels of control of the process variables, for example reduced precursor consumption through lower input flux, lower reactor and hence substrate temperature which decreases stresses and non-uniformities in the secondary substrate leading to more uniform graphene production on the substrate surface and hence, in most cases, significantly reduced process time.

Experimentation suggests a maximum spacing of about 100 mm is suitable. However, more reliable and better quality two- dimensional crystalline material is produced using a much smaller spacing equal to or less than about 20 mm, such as 1 to 5 mm; a spacing equal or less than about 10 mm promotes the formation of stronger thermal currents proximate the secondary substrate surface that increase production efficiency.

Where a precursor is used that has a relative low decomposition temperature such that there is likely to be a more than negligible degree of decomposition of the precursor at the temperature of the precursor inlet, a spacing below 10 mm is strongly preferred to minimise the time taken for the precursor to reach the substrate.

During the production method, a flow is supplied comprising a precursor compound through the inlets and into the reaction chamber to thereby decompose the precursor compound and form graphene on the secondary substrate. The flow comprising a precursor compound may further comprise a dilution gas. Suitable dilution gases are discussed in more detail below.

Preferably the precursor compound is a hydrocarbon. Preferably the precursor compound is a hydrocarbon which is a liquid at room temperature. Preferred embodiments include C₅ to C₁₀ alkanes. The use of simple hydrocarbons are preferred since this gives a pure source of carbon with gaseous hydrogen as a by-product. In addition, since the hydrocarbons are liquid at room temperature, they can be obtained in a highly pure liquid form at low cost. Preferably the precursor compound is hexane. Nonetheless, other compounds such as a halomethane or metallocene would be equally as useful as they can potentially dope the layer while still delivering highly transparent material.

The precursor is preferably in the gas phase when passed over the heated secondary substrate. There are two variables to be considered: pressure within the close coupled reaction chamber and the gas flow rate into the chamber.

The preferred pressure selected depends upon the precursor chosen. In general terms, where precursors of greater molecular complexity are used, improved two- dimensional crystalline material quality and rate of production is observed using lower pressures, e.g. less than 500 m bar. Theoretically, the lower the pressure the better, but the benefit provided by very low pressures (e.g. less than 200 mbar) will be offset by very slow graphene formation rates.

Conversely for less complex molecular precursors, higher pressures are preferred. For example where methane is used as a precursor for graphene production, a pressure of 600 mbar or greater may be suitable. Typically, it is not expected to use pressures greater than atmospheric because of its detrimental impact on secondary substrate surface kinetics and the mechanical stresses placed on the system. A suitable pressure can be selected for any precursor through simple empirical experimentation, which may involve for example, five test runs using respective pressures of 50 mbar, 950 mbar and three others of equidistance intervals between the first two. Further runs to narrow the most suitable range can then be conducted at pressures within the interval identified in the first runs as being most suitable. The preferred pressure for hexane is from 50 to 800 m bar.

The precursor flow rate can be used to control the graphene deposition rate. The flow rate chosen will depend upon the amount of the species within the precursor and the area of the layer to be produced. Precursor gas flow rate needs to be high enough to allow coherent graphene layer formation on the substrate surface. If the flow is above an upper threshold rate, bulk material formation, e.g. graphite, will generally result or increased gas phase reactions will occur resulting in solid particulates suspended in the gas phase that are detrimental to graphene formation and/or may contaminate the graphene layer. The minimum threshold flow rate can be theoretically calculated using techniques known to the person skilled in the art, by assessing the amount of the species required to be supplied to the substrate to ensure sufficient atomic concentrations are available at the secondary substrate surface for a layer to form. Between the minimum and upper threshold rates, for a given pressure and temperature, flow rate and graphene layer growth rate are linearly related.

Preferably a mixture of the precursor with a dilution gas is passed over the heated substrate within a close coupled reaction chamber. The use of a dilution gas allows further refinement of the control of the carbon supply rate.

It is preferred that the dilution gas includes one or more of hydrogen, nitrogen, argon and helium. These gases are selected because they will not readily react with a large number of available precursors under typical reactor conditions, nor be included in the graphene layer. Notwithstanding, hydrogen may react with certain precursors. Additionally, nitrogen can be incorporated into the graphene layer under certain conditions. In such instances one of the other dilution gases can be used.

In spite of these potential problems, hydrogen and nitrogen are particularly preferred because they are standard gases used in MOCVD and VPE systems.

The susceptor is heated to a temperature of at least 50° C. in excess of a decomposition temperature of the precursor, more preferably from 100 to 200° C. in excess. The preferred temperature to which the secondary substrate is heated is dependent upon the precursor selected. The temperature selected needs to be high enough to allow at least partial decomposition of the precursor in order to release the species, but preferably not so high as to promote increased recombination rates in the gas phase away from the secondary substrate surface and hence production of unwanted by-products. The selected temperature is higher than the complete decomposition temperature to promote improved substrate surface kinetics and so encourage formation of graphene with good crystal quality. For hexane, the most preferred temperature is about 1200° C., such as from 1150 to 1250° C.

In order for there to be a thermal gradient between the secondary substrate surface and the introduction point for precursor, the inlet will need to be of a lower temperature than the secondary substrate. For a fixed separation a greater temperature difference will provide a steeper temperature gradient. As such it is preferred that at least the wall of the chamber through which the precursor is introduced, and more preferably the walls of the chamber are cooled. Cooling may be achieved using a cooling system, for example, using fluid, preferably liquid, most preferably water, cooling. The reactor's walls may be maintained at constant temperature by water cooling. The cooling fluid may flow around the inlet(s) to ensure that the temperature of the inner surface of the reactor wall through which the inlets extend, and thus of the precursor itself as it passes through the inlet and into the reaction chamber, is substantially lower than the substrate temperature. The inlets are cooled to less than 100° C., preferably 50 to 60° C.

Where the method further comprises a step of using a laser to selectively ablate graphene from the substrate to shape the contacts, suitable lasers are those having wavelength in excess of 600 nm and a power of less than 50 Watts. Preferably the laser has a wavelength of from 700 to 1500 nm. Preferably the laser has a power of from 1 to 20 Watts. This allows the graphene to be readily removed without damaging the neighbouring graphene or the substrate.

Preferably the laser spot size is kept as small as possible (i.e. have a better resolution). For example, the present inventors have worked at a spot size of 25 microns. Focus should be as precise as possible. It has also been found that it is better to pulse the laser as opposed to continuous lasing, in order to prevent substrate damage.

According to one embodiment, a laser is used to selectively ablate graphene to thereby define a wire circuit on the device for connection to electronic components to form an electrical circuit on the device. This form of integrated device is particularly space efficient.

For some embodiments it may be desirable to dope the graphene. This may be achieved by introducing a doping element into the close coupled reaction chamber and selecting a temperature of the substrate, a pressure of the reaction chamber and a gas flow rate to produce a doped graphene. Straightforward empirical experimentation can be used to determine these variables using the guidance described above. This process can be used with or without a dilution gas.

There is no perceived restriction as to doping element that may be introduced. Commonly used dopant elements for the production of graphene include silicon, magnesium, zinc, arsenic, oxygen, boron, bromine and nitrogen.

Elements of the above-described method will now be discussed in more detail.

A close coupled reaction chamber provides a separation between the secondary substrate surface upon which the graphene is formed and the entry point at which the precursor enters the close coupled reaction chamber that is sufficiently small that the fraction of precursor that reacts in the gas phase within the close coupled reaction chamber is low enough to allow the formation of graphene. The upper limit of the separation may vary depending upon the precursor chosen, substrate temperate and pressure within the close coupled reaction chamber.

Compared with the chamber of a standard CVD system, the use of a close coupled reaction chamber, which provides the aforementioned separation distance, allows a high degree of control over the supply of the precursor to the secondary substrate; the small distance provided between the secondary substrate surface on which the graphene is formed and the inlet through which the precursor enters the close coupled reaction chamber, allows for a steep thermal gradient thereby providing a high degree of control over the decomposition of the precursor.

The relatively small separation between the secondary substrate surface and the chamber wall provided by a close coupled reaction chamber, compared with the relatively large separation provided by a standard CVD system allows:

1) a steep thermal gradient between the precursor's entry point and the secondary substrate surface;

2) a short flow path between the precursor entry point and the secondary substrate surface; and

3) a close proximity of the precursor entry point and the point of graphene formation.

These benefits enhance the effects that deposition parameters including substrate surface temperature, chamber pressure and precursor flux have on the degree of control over the delivery rate of the precursor to the substrate surface and the flow dynamics across the secondary substrate surface.

These benefits and the greater control provided by these benefits enable minimisation of gas phase reactions within the chamber, which are detrimental graphene deposition; allow a high degree of flexibility in the precursor decomposition rate, enabling efficient delivery of the species to the substrate surface; and gives control over the atomic configuration at the substrate surface which is impossible with standard CVD techniques

Through both simultaneously heating the substrate and providing cooling to the wall of the reactor directly opposite the substrate surface at the inlet, a steep thermal gradient can be formed whereby the temperature is a maximum at the substrate surface and drops rapidly towards the inlet. This ensures the reactor volume above the substrate surface has a significantly lower temperature than the substrate surface itself, largely reducing the probability of precursor reaction, in the gas phase, until the precursor is proximate the substrate surface.

An alternative design of MOCVD reactor is also contemplated which has been demonstrated to be efficient for graphene growth as described herein. This alternative design is a so-called High Rotation Rate (HRR) or “Vortex” flow system. Whereas the close-coupled reactor described above focussed on creating graphene using a very high thermal gradient, the new reactor has a significantly wider spacing between the injection point and growth surface or substrate. Close coupling allowed extremely rapid dissociation of precursors delivering elemental carbon, and potentially other doping elements, to the substrate surface allowing the formation of graphene layers. In contrast, the new design relies on a vortex of the precursors.

In the new reactor design, in order to promote laminar flow over the surface this system utilizes a higher rotation rate to impinge a high level of centrifugal acceleration on the injected gas stream. This results in a vortex type fluid flow within the chamber. The effect of this flow pattern is a significantly higher residency time of the precursor molecules proximate to the growth/substrate surface compared to other reactor types. For the deposition of graphene this increased time is what promotes the formation of elemental layers.

However, this type of reactor does have a couple of parasitic issues, firstly the amount of precursor required to achieve the same amount of growth as other reactors increases due to the reduced mean free path that this flow regime causes, resulting in more collisions of precursor molecules delivering non-graphene growth atomic recombination. However, the use of reagents such as hexane which are relatively cheap means that this problem can be readily overcome. Additionally, the centrifugal motion has varying impacts on atoms and molecules of different sizes resulting in the ejection of different elements at different velocities. While this probably assists graphene growth due to the uniform rate of carbon supply with ejection of unwanted precursor by-products it can be detrimental to desired effects such as elemental doping. It is therefore preferred to use this design of reactor for undoped graphene.

An example of such a reaction system is the Veeco Instruments Inc. Turbodisc technology, K455i or Propel tools.

Preferably the reactor used herein in a high rotation rate reactor. This alternative design of reactor may be characterised by its increased spacing and high rotation rate. Preferred spacings are from 50 to 120 mm, more preferably 70 to 100 mm. The rotation rate is preferably from 100 rpm to 3000 rpm, preferably 1000 rpm to 1500 rpm.

According to an alternative aspect, there is provided a method for the production of a light-sensitive or light-emitting electronic device, and comprises:

providing a light-sensitive or light-emitting device as a substrate on a heated susceptor in a reaction chamber, the chamber having a plurality of cooled inlets arranged so that, in use, the inlets are distributed across the substrate and have a constant separation from the substrate,

supplying a flow comprising a precursor compound through the inlets and into the reaction chamber to thereby decompose the precursor compound and form graphene on the substrate,

wherein the inlets are cooled to less than 100° C., preferably 50 to 60° C., and the susceptor is heated to a temperature of at least 50° C. in excess of a decomposition temperature of the precursor,

and thereby forming a graphene layer structure on the light-sensitive or light-emitting device;

wherein the graphene layer structure comprises from 2 to 6 layers of graphene and wherein the graphene layer structure is for providing an electrical contact for the device. Preferably the light-sensitive or light-emitting device is formed by MOCVD in an MOCVD reaction chamber beforehand and preferably the MOCVD chamber is the same one used to form the graphene layer structure so that the device does not need to be removed from the MOCVD chamber between steps and the method is faster and more efficient.

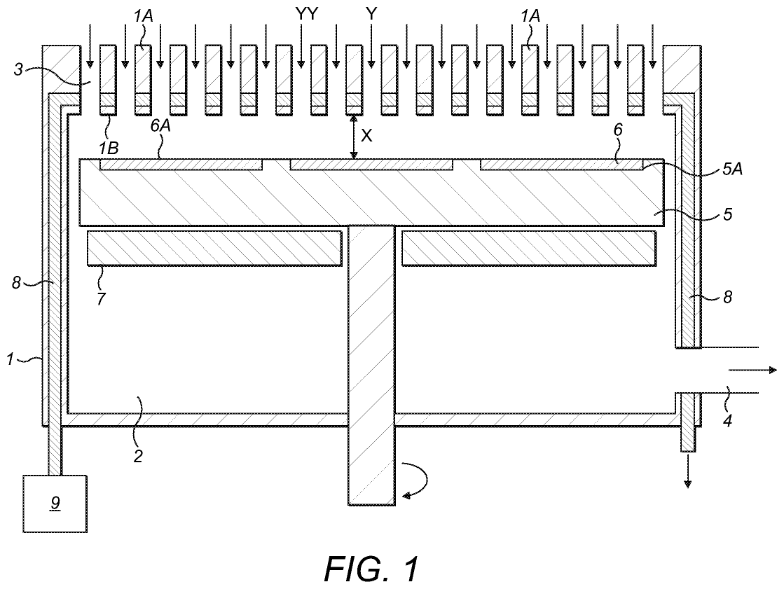

The reactor of FIG. 1 is constructed for the deposition of a graphene layer on a substrate through the method of Vapour Phase Epitaxy (VPE), in which a precursor is introduced to thermally, chemically and physically interact in the vicinity of and on the secondary substrate to form a graphene layer structure having from 2 to graphene layers. The same apparatus may be used for an initial step of forming an optical device on a primary substrate.

The apparatus comprises a close coupled reactor 1 having a chamber 2 having an inlet or inlets 3 provided through a wall 1A and at least one exhaust 4. A susceptor 5 is arranged to reside within the chamber 2. The susceptor 5 comprises one or more recesses 5A for retaining one or more substrates 6. The apparatus further comprises means to rotate the susceptor 5 within the chamber 2; and a heater 7, e.g. comprising a resistive heating element, or RF induction coil, coupled to the susceptor 5 to heat the substrate 6. The heater 7 may comprise a single or multiple elements as required to achieve good thermal uniformity of the substrate 6. One or more sensors (not shown) within the chamber 2 are used, in conjunction with a controller (not shown) to control the temperature of the substrate 6.

The temperature of the walls of the reactor 1 is maintained at substantially constant temperature by water cooling.

The reactor walls define one or more internal channels and/or a plenum 8 that extend substantially adjacent (typically a couple of millimetres away) the inner surface of reactor walls including inner surface IB of wall 1A. During operation, water is pumped by a pump 9 through the channels/plenum 8 to maintain the inside surface 1B of wall 1A at or below 200° C. In part because of the relatively narrow diameter of the inlets 3, the temperature of the precursor (which is typically stored at a temperature much below the temperature of inside surface 1B), as it passes through inlets 3 through wall 1A into the chamber 1 will be substantially the same or lower than the temperature of the inside surface 1B of wall 1A.

The inlets 3 are arranged in an array over an area that is substantially equal or greater than the area of the one or more substrates 6 to provide substantially uniform volumetric flow over substantially the entirety of surfaces 6A of the one or more substrates 6 that face the inlets 3.

The pressure within the chamber 2 is controlled through control of precursor gas flows through inlet(s) 3 and exhaust gas through exhaust 4. Via this methodology, the velocity of the gas in the chamber 2 and across the substrate surface 6A and further the mean free path of molecules from the inlet 3 to substrate surface 6A are controlled. Where a dilution gas is used, control of this may also be used to control pressure through inlet(s) 3. The precursor gas is preferably hexane.

The susceptor 5 is comprised from a material resistant to the temperatures required for deposition, the precursors and dilution gases. The susceptor 5 is usually constructed of uniformly thermally conducting materials ensuring substrates 6 are heated uniformly. Examples of suitable susceptor material include graphite, silicon carbide or a combination of the two.

The substrate(s) 6 are supported by the susceptor 5 within the chamber 2 such that they face wall 1A with a separation, denoted in FIG. 1 by X, of between 1 mm-100 mm, though, as discussed above, generally the smaller the better. Where the inlets 3 protrude into or otherwise sit within the chamber 2, the relevant separation is measured between the substrate(s) 6 and exit of the inlets 3.

The spacing between the substrate 6 and the inlets 3 may be varied by moving the susceptor 5, substrate 6 & heater 7.

An example of a suitable close coupled reactor is the AIXTRON® CRIUS MOCVD reactor, or AIXTRON® R&D CCS system.

Precursors in gaseous form or in molecular form suspended in a gas stream are introduced (represented by arrows Y) into the chamber 2 through inlets 3 such that they will impinge on or flow over the substrate surface 6A. Precursors that may react with one another are kept separated until entering the chamber 2 by introduction through different inlets 3. The precursor or gas flux/flow rate is controlled externally to the chamber 2 via a flow controller (not shown), such as a gas mass flow controller.

A dilution gas may be introduced through an inlet or inlets 3 to modify gas dynamics, molecular concentration and flow velocity in the chamber 2. The dilution gas is usually selected with respect to the process or substrate 6 material such that it will not have an impact on the growth process of the graphene layer structure. Common dilution gases include Nitrogen, Hydrogen, Argon and to a lesser extent Helium.

After the graphene layer structure having from 2 to 6 graphene layers has been formed, the reactor is then allowed to cool and the substrate 6 is retrieved providing a device having the graphene layer structure thereon.

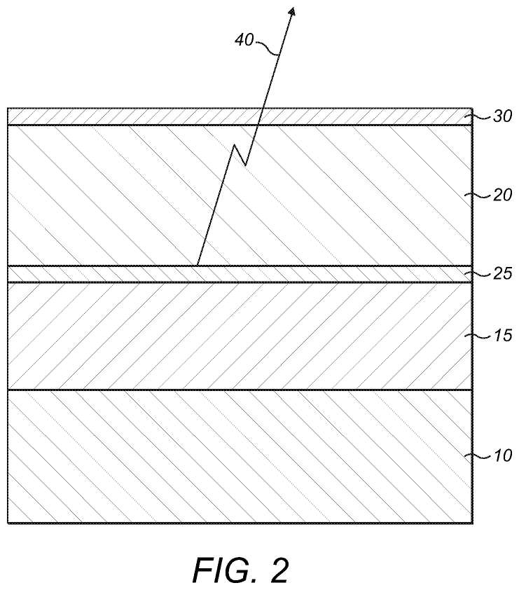

FIG. 2 shows an exemplary LED device structure. This device has an electrically conductive substrate 10, on which an n-doped GaN layer 15 is formed. This is separated from a p-doped GaN layer 20 by a MQW layer 25. Finally a graphene layer structure 30 is provided as an electrical contact as the uppermost layer. The graphene layer structure 30 is optically transparent to permit the emission of light as shown by arrow 40.

### EXAMPLES

The present invention will now be described further with reference to the following non-limiting examples.

The following describes example processes using the aforementioned apparatus that successfully produced graphene layer structure having from 2 to 6 graphene layers. In all examples a close coupled vertical reactor of diameter 250 mm with six 2″(50 mm) target substrates were used. For reactors of alternate dimensions and/or different target substrate areas, the precursor and gas flow rates can be scaled through theoretical calculation and/or empirical experimentation to achieve the same results.

Using the method of the invention it has been possible to produce patterned graphene with substantially improved properties over known methods, for example with a grain size greater than 20 μm, covering a substrate of 6 inch diameter with 98% coverage, a layer uniformity of >95% of the substrate, sheet resistivity less than 450 Q/sq and electron mobility greater than 2435 cm²/Vs. The most recent tests on a graphene layer produced using the method of the invention have demonstrated electron mobility>8000 cm²/V s across the full layer tested at standard conditions for temperature and pressure. The method has been able to produce graphene layers across a substrate of 6 inches (15 cm) having undetectable discontinuity, measured by standard Raman and AFM mapping techniques to micron scale. The method has also shown to be able to produce a uniform graphene monolayer and stacked uniform graphene layers across the substrate without formation of additional layer fragments, individual carbon atoms or groups of carbon atoms on top of the or uppermost uniform monolayer.

### Example 1

The reactor was heated to 1100 degrees Celsius and pumped to a pressure of 100 mbar in the presence of hydrogen carrier gas. 20000 sccm of hydrogen gas was used. The wafers were baked in the hydrogen gas at this temperature for 5 minutes.

The reactor was subsequently cooled to 540 degrees Celsius where approximately 20 nm of GaN was grown by introducing NH₃ gas at a flow of 1200 sccm and TMGa at a flow of 45 sccm where the TMGa precursor was held at a pressure of 1900 mbar and a precursor temperature of 5 degrees Celsius.

Next the reactor was heated to 1050 degrees Celsius and GaN was grown with an NH₃ flow of 5500 sccm and a TMGa flow of 85 sccm for 1 hour to a thickness of approximately 2.5 μm. The NH₃ and TMGa flows were maintained and silane at a concentration of 50 ppm was introduced to the reactor at a flow rate to give a silicon doping concentration of 5e18cm⁻³. This silicon doped layer of GaN was grown for 1 hour to a thickness of 2.5 μm.

The TMGa and silane flows were turned off to the reactor, the reactor was cooled to 750 degrees Celsius and the reactor pressure was increased to 400 mbar. The carrier gas was changed from H₂ to N₂. 6 quantum barriers of thickness 10 nm each were grown at this temperature with a NH₃ flow of 8000 sccm and a TEGa flow of 90 sccm where the TEGa precursor was held at a pressure of 1300 mbar and a temperature of 20 degrees Celsius.

5 quantum wells of thickness 3nm each were also grown using the same NH₃ and TEGa conditions and by introducing TMIn to the reactor at a flow of 180 sccm where the TMIn precursor was held at a temperature of 25 degrees Celsius and a pressure of 1300 mbar. The TEGa and TMIn flows to the reactor were turned off and the carrier gas was changed back to H₂.

The NH3 flow was changed to 5000 sccm and the reactor was increased to 950 degrees Celsius and the reactor pressure was decreased to 100 mbar. A 20 nm layer of p-type AIGaN was grown by introducing TMGa at a flow of 40 sccm and TMAI at a flow of 60 sccm where the TMAI precursor was held at a temperature of 20 degrees Celsius and a pressure of 1300 mbar.

Cp2Mg was concurrently introduced at a flow of 600 sccm where the Cp2Mg precursor was held at a pressure of 1300 mbar and a temperature of 32 degrees Celsius. In this case the Mg acts as the p dopant in the AIGaN layer. The TMAI flow to the reactor was turned off and p-type GaN was grown using the same flows of all gases and precursors to a thickness of approximately 200 nm.

Next the TMGa and Cp2Mg flows were turned off and the reactor was cooled to 900 degrees Celsius. At this temperature the carrier gas was changed from H₂ to N₂ and the NH₃ flow was turned off.

Toluene was introduced to the reactor next as the precursor for graphene growth. The toluene flow was 120 sccm where the toluene precursor was held at a temperature of 15 degrees Celsius and a pressure of 900 mbar. Growth continued for 7 minutes until 3 layers of graphene had been deposited. The toluene flow to the reactor was turned off and the reactor was cooled to 800 degrees Celsius. The wafers were annealed at this temperature for 20 minutes in the N₂ carrier gas in order to activate the Mg atoms in the p-type layers. Finally, the reactor was cooled to room temperature in a 8 minute temperature ramp.

In this way an LED was formed with a graphene surface electrode having good electrical and optical transparency properties. The electrical properties are measured using van der Pauw Hall measurements, which allows for the sheet resistance and resistivity of the layer, amongst other properties, to be ascertained. The optical transparency can be measured with a transparency meter. The graphene contacted layer resulted in a factor of 2 reduction in the contact resistance, as compared to an identical LED with conventional contacts, and a >5% increase in emission brightness.

All percentages herein are by weight unless otherwise stated.

The foregoing detailed description has been provided by way of explanation and illustration, and is not intended to limit the scope of the appended claims. Many variations in the presently preferred embodiments illustrated herein will be apparent to one of ordinary skill in the art, and remain within the scope of the appended claims and their equivalents.

1. A method for the production of a light-sensitive or light-emitting electronic device, the method comprising:
forming a light-sensitive or light-emitting device by MOCVD in an MOCVD reaction chamber;
forming a graphene layer structure on the light-sensitive or light-emitting device in the MOCVD reaction chamber;
wherein the graphene layer structure comprises from 2 to 10 layers of graphene, and wherein the graphene layer structure is for providing an electrical contact for the device.

2. The method according to claim 1, wherein the light-emitting device is a UV LED and wherein the graphene layer structure comprises from 2 to 6 layers of graphene.

3. The method according to claim 1, wherein the light-sensitive device is a solar panel.

4. The method according to claim 1, wherein the graphene layer structure comprises 3 or 4 layers of graphene.

5. The method according to claim 1 wherein the step of forming a graphene layer structure on the light-sensitive or light-emitting device in the MOCVD reaction chamber comprises:
providing the light-sensitive or light-emitting device as a substrate on a heated susceptor in a reaction chamber, the chamber having a plurality of cooled inlets arranged so that, in use, the inlets are distributed across the substrate and have a constant separation from the substrate,
supplying a flow comprising a precursor compound through the inlets and into the reaction chamber to thereby decompose the precursor compound and form graphene on the substrate,
wherein the inlets are cooled to less than 100° C., and the susceptor is heated to a temperature of at least 50° C. in excess of a decomposition temperature of the precursor.

6. The method according to claim 5, wherein the precursor compound is a hydrocarbon.

7. The method according to claim 1, wherein the method further comprises connecting the graphene-layer-structure-coated light-sensitive or light-emitting device into a circuit, wherein at least a portion of the graphene provides an electrical contact for the device.

8. The method according to claim 5, wherein the method further comprises connecting the graphene-layer-structure-coated light-sensitive or light-emitting device into a circuit, wherein at least a portion of the graphene provides an electrical contact for the device.

9. The method according to claim 5, wherein the precursor compound is a hydrocarbon which is a liquid at room temperature.

10. The method according to claim 5, wherein the precursor compound is a C₅ to C₁₀ alkane.
